(19) United States
(12) Patent Application Publication
(10) Pub. No.: US 2026/0313847 A1
(43) Pub. Date: Oct. 8, 2026

(54) INTEGRATED DIAMOND MANIFOLD MICROCHANNEL HEAT SINK STRUCTURE AND MANUFACTURING METHOD THEREOF

(71) Applicant: Xi'an Jiaotong University, Xi'an (CN)

(72) Inventors: Jianlei Cui, Xi'an (CN); Haozhe Kang, Xi'an (CN); Xuesong Mei, Xi'an (CN); Zhengjie Fan, Xi'an (CN); Zheng Sun, Xi'an (CN); Wenjun Wang, Xi'an (CN); Wanqin Zhao, Xi'an (CN); Bin Liu, Xi'an (CN)

(21) Appl. No.: 19/577,861

(22) Filed: Mar. 25, 2026

(30) Foreign Application Priority Data
Apr. 7, 2025 (CN) 2025104265847

(51) Int. Cl. H05K 7/20

(52) U.S. Cl. CPC H05K 7/2039

(57) ABSTRACT

An integrated diamond manifold microchannel heat sink structure and a manufacturing method thereof are provided. The heat sink structure includes a microchannel structure, a manifold structure and a manifold plate. The manifold structure and microchannel structure are integrated on a diamond substrate. The microchannel structure is connected to the manifold structure, and a microchannel structure surface is sealed. The manifold structure is connected to the manifold plate. The manifold plate is defined with flow-guiding structures penetrating therethrough. The heat sink structure features fewer heterogeneous interfaces. During fabrication, the manifold structure and microchannel structure are fabricated on two opposite sides of the diamond substrate using an ultraviolet nanosecond laser processing system, followed by epitaxial lateral growth of the diamond on the microchannel structure surface via microwave plasma chemical vapor deposition until tops of microchannels are sealed. The manifold plate is bonded to an upper surface of the manifold structure by brazing.

### CROSS-REFERENCE TO RELATED APPLICATION

This application claims priority to Chinese patent application No. CN202510426584.7, filed to China National Intellectual Property Administration (CNIPA) on Apr. 7, 2025, which is herein incorporated by reference in its entirety.

### TECHNICAL FIELD

The disclosure belongs to the technical field of heat dissipation for electronic devices with extremely high heat flux, more particularly relates to an integrated diamond manifold microchannel heat sink structure for active cooling of electronic chips and devices with extremely high heat flux, and provides a practically feasible manufacturing method for this novel structure.

### BACKGROUND

Over recent decades, rapid advancements of photolithography and advanced packaging technologies have led to a continuous increase in a number of transistors integrated into circuits within various devices, while their physical dimensions have been consistently shrinking. This trend results in generation of more heat within already confined space of chips, thereby causing a sharp rise in the heat flux of devices. Researches indicate that an increase in junction temperature significantly impacts device lifetime. The higher the junction temperature, the shorter the device lifetime. Consequently, efficiently and reliably removing waste heat generated by high-performance chips or devices has become a critical challenge in the field of thermal management for electronic devices, which, to some extent, has limited further improvements in chip integration density and performance. With advances in fabrication techniques and related researches of thermal management, active cooling technology has emerged as a key solution for cooling high-power devices, with applications already demonstrated in gallium nitride power devices. Specifically, a manifold microchannel heat sink serves as a core component of the active cooling technology.

The current manifold microchannel heat sinks are manufactured from a variety of materials, primarily copper, aluminum, silicon, and some organic materials. From a performance standpoint, diamond is undoubtedly an excellent material for manufacturing the manifold microchannel heat sinks due to its ultra-high thermal conductivity. However, the current use of the diamond for manufacturing the manifold microchannel heat sinks faces the following challenges. Existing structures and manufacturing processes for the manifold microchannel heat sinks are not suitable for the diamond, thereby necessitating a redesign of both the heat sink structure and the manufacturing process for the diamond. The typical current manifold microchannel heat sink primarily consists of four components: a manifold plate, a manifold layer, a microchannel layer, and a baseplate. These components are often manufactured separately (which also allows for the use of different materials) and subsequently assembled using techniques such as bonding, adhesive bonding, or mechanical sealing. This process is relatively cumbersome and requires pretreatment of multiple mating surfaces based on specific bonding technologies prior to bonding, leading to a reduction in reliability of the entire heat sink. Moreover, this process introduces heterogeneous interfaces between the components. These heterogeneous interfaces typically consist of materials with relatively low thermal conductivity, and even the most advanced bonding technologies exhibit interfacial thermal conductivity far lower than that of the diamond. Consequently, this limits the cooling performance of the diamond heat sink, contradicts the original intent of using high thermal conductivity materials for the manifold microchannel heat sinks, and involves higher technical complexity and cost.

### SUMMARY

The key technical problem addressed by the disclosure is to overcome the shortcomings of the related art described above, and to provide an integrated diamond manifold microchannel heat sink structure and its manufacturing method with practical engineering applicability.

In a first aspect, the disclosure provides an integrated diamond manifold microchannel heat sink structure, including: a microchannel structure, a manifold structure, and a manifold plate. The manifold structure and the microchannel structure are both integrated on a diamond substrate. The microchannel structure is connected to the manifold structure, and a surface where the microchannel structure is located is sealed. The manifold structure is connected to the manifold plate. The manifold plate is defined with flow-guiding structures penetrating therethrough.

In an embodiment, the diamond substrate has a thickness of 0.6 millimeters (mm); the manifold structure is machined to a depth of 0.25 mm; and the microchannel structure has a depth of 0.35 mm.

In a second aspect, the disclosure provides a manufacturing method for the integrated diamond manifold microchannel heat sink structure as described above, including the following steps:

based on an ultraviolet nanosecond laser processing system, removing materials from one side of a double-side polished diamond substrate by using manifold processing parameters according to a designed shape of the manifold structure to obtain a diamond substrate with a machined manifold structure;

based on the ultraviolet nanosecond laser processing system, flipping the diamond substrate with the machined manifold structure by 180°, and removing materials from the other side of the diamond substrate with the machined manifold structure by using microchannel processing parameters according to a designed shape of the microchannel structure to form the microchannel structure, where the microchannel structure is connected to the manifold structure;

performing epitaxial lateral growth on a microchannel side of the diamond substrate with the manifold structure and the microchannel structure until a top of the microchannel structure is sealed;

based on the ultraviolet nanosecond laser processing system, processing a double-side polished silicon wafer by using the manifold processing parameters according to a designed shape of the flow-guiding structures, where the flow-guiding structures penetrate through upper and lower surfaces of the silicon wafer, thereby obtaining the manifold plate;

metallizing a side of the manifold plate and a surface of the manifold structure to obtain a metallized manifold plate and a metallized manifold structure;

bonding the metallized manifold plate and the metallized manifold structure.

In an embodiment, in the ultraviolet nanosecond laser processing system, a laser has a central wavelength of 355 nanometers (nm) and a pulse width of 15 nanoseconds (ns).

In an embodiment, for all laser processing steps, laser parameters are used as follows: a power of 10.5 watts (W), and a repetition rate of 50 kilohertz (kHz).

In an embodiment, after the top of the microchannel structure is sealed, the diamond substrate with the epitaxial lateral growth is polished to achieve a surface roughness below 0.1 micrometers (μm).

In an embodiment, a processing area of the manifold structure is divided into a structural contour and an internal fill. A scanning speed along the structural contour is 500 millimeters per second (mm/s), with 200 clockwise passes and 200 counterclockwise passes. For the internal fill, a crisscross pattern with a 1 μm pitch is employed, with a scanning speed of 240 mm/s and a single pass.

In an embodiment, a processing area of the microchannel structure is divided into a structural contour and an internal fill. The scanning speed along the structural contour is 500 mm/s, with 400 clockwise passes and 400 counterclockwise passes. For the internal fill, a crisscross pattern with a 1 μm pitch is used, processed in two stages to achieve a depth of 350 μm with one of the two stages at a scanning speed of 340 mm/s and the other of the two stages at a scanning speed of 430 mm/s.

In an embodiment, when metallizing the side of the manifold plate and the surface of the manifold structure, a magnetron sputtering process is employed to deposit a titanium (Ti) film onto the side of the manifold plate and the surface of the manifold structure; during deposition, a substrate temperature is maintained at 220 Celsius degrees (℃), with a vacuum degree below 5×10⁻⁵ pascals (Pa).

In an embodiment, when bonding the metallized manifold plate and the metallized manifold structure, a vacuum brazing process is employed, with a high thermal resistance bonding method.

Compared with the related art, the disclosure has at least the following beneficial effects. The integrated diamond manifold microchannel heat sink structure proposed by the disclosure features fewer heterogeneous interfaces (only one, as opposed to typically at least three in conventional designs), thereby significantly reducing reliance on vacuum deposition and low-thermal-resistance vacuum brazing technologies required by conventional manufacturing processes. The manifold structure and the microchannel structure are machined in a single process on the same diamond substrate, thereby reducing a frequency of sample changes and facilitating higher automation in the manufacturing process. An integrated design of the manifold and the microchannels, compared to traditional manifold heat sinks, not only enables heat exchange between the microchannels and a liquid coolant but also allows the manifold to fully utilize its intrinsic properties to participate in active cooling, thereby significantly enhancing cooling performance of the heat sink. Furthermore, the manufacturing method for the integrated diamond manifold microchannel heat sink structure proposed by the disclosure substantially simplifies the manufacturing process and reduces manufacturing cost.

### BRIEF DESCRIPTION OF DRAWINGS

FIG. 1 illustrates a schematic structural diagram of an ultraviolet nanosecond laser processing system according to the disclosure.

FIG. 2 illustrates a schematic diagram of a flipping fixture that can be connected to a stepper motor according to the disclosure.

FIG. 3 illustrates a schematic diagram of a manifold plate with a water inlet hole and a water outlet hole according to the disclosure.

FIG. 4 illustrates a schematic diagram of an integrated diamond manifold microchannel structure (a manifold layer and a microchannel layer are shown as separate parts for ease of understanding) according to the disclosure.

FIG. 5 illustrates a schematic diagram of an integrated diamond manifold microchannel heat sink structure according to the disclosure.

In the accompanying drawings, description of reference signs is listed as follows:

1. microchannel structure; 2. manifold structure; 3. manifold plate; 4. diamond substrate; 5. water inlet hole; 6. water outlet hole; 7. flipping fixture; 701. flipping fixture body; 702. groove; 703. clamping block; 9. ultraviolet nanosecond laser processing system; 901. laser; 12. inlet manifold; 13. outlet manifold.

### DETAILED DESCRIPTION OF EMBODIMENTS

To make the objectives, technical solutions, and advantages of the disclosure clearer and more comprehensible, the disclosure is further described in detail below in conjunction with the accompanying drawings and specific embodiments. It should be understood that the specific embodiments described herein are intended only to explain the disclosure and not to limit its scope.

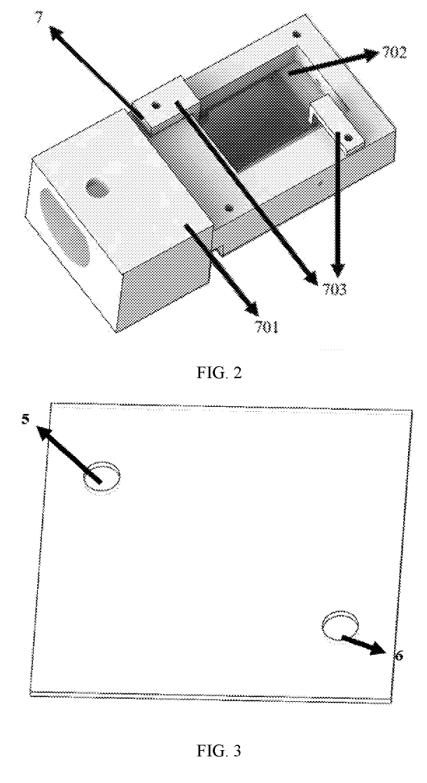

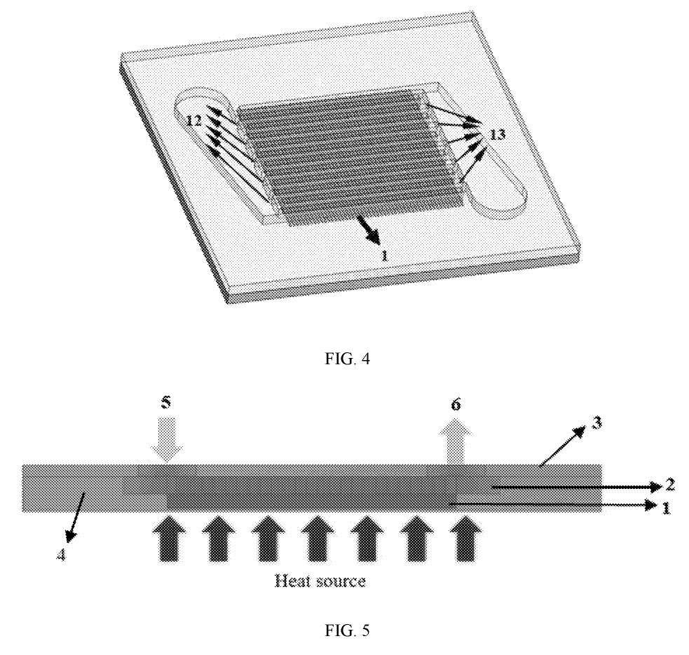

As shown in FIGS. 2, 3, 4, and 5, the disclosure provides an integrated diamond manifold microchannel heat sink structure, including: a microchannel structure 1, a manifold structure 2, and a manifold plate 3. The manifold structure 2 and the microchannel structure 1 are fabricated on two opposite sides of a same diamond substrate 4 by using an ultraviolet nanosecond laser processing system 9, followed by epitaxial lateral growth of the diamond on the microchannel structure surface via microwave plasma chemical deposition until tops of microchannels are sealed. This process achieves manufacturing and integration of the manifold structure 2, the microchannel structure 1 and a baseplate on a single diamond piece. Finally, the manifold plate 3 is bonded to an upper surface of the manifold structure 2 by brazing. The resulting structure can be integrated into a pump-driven heat transfer fluid loop. This design fully leverages ultra-high thermal conductivity of the diamond, significantly simplifies the manufacturing process and reduces manufacturing costs.

A specific manufacturing method for the integrated diamond manifold microchannel heat sink structure described in the disclosure employs an ultraviolet nanosecond laser processing system 9. A laser 901 has a central wavelength of 355 nm and a pulse width of 15 ns. The system is provided with a beam expander, an aperture, multiple reflective mirrors, a two-dimensional (2D) scanning galvanometer, an F-theta (F-θ) lens, a three-dimensional (3D) motion platform, a charge-coupled device (CCD) camera, and a computer for system control. All laser processing is performed on a specially designed flipping fixture 7 capable of 180° flipping. The ultraviolet nanosecond laser processing system 9 is sequentially arranged along an optical path, consisting of an ultraviolet nanosecond laser 901, the beam expander, the aperture, two reflective mirrors, the 2D scanning galvanometer, the F-θ lens, and the 3D motion platform. The flipping fixture 7 is disposed on the 3D motion platform.

In an embodiment of the disclosure, a groove 702 for clamping the diamond substrate 4 is defined on a flipping fixture body 701. A clamping block 703 is disposed along an edge of the groove 702 and is secured to the flipping fixture body 701 via screws, with the pressure exerted by the clamping block 703 oriented perpendicular to a surface of the diamond substrate 4 to be processed.

An end of the flipping fixture body 701 is connected to an output shaft of a stepper motor.

In an embodiment of the disclosure, a position of the clamping block 703 is adjustable. The flipping fixture body 701 is provided with multiple holes or an elongated slot for fixing the clamping block 703. The clamping block 703 is secured to the flipping fixture body 701 via bolts.

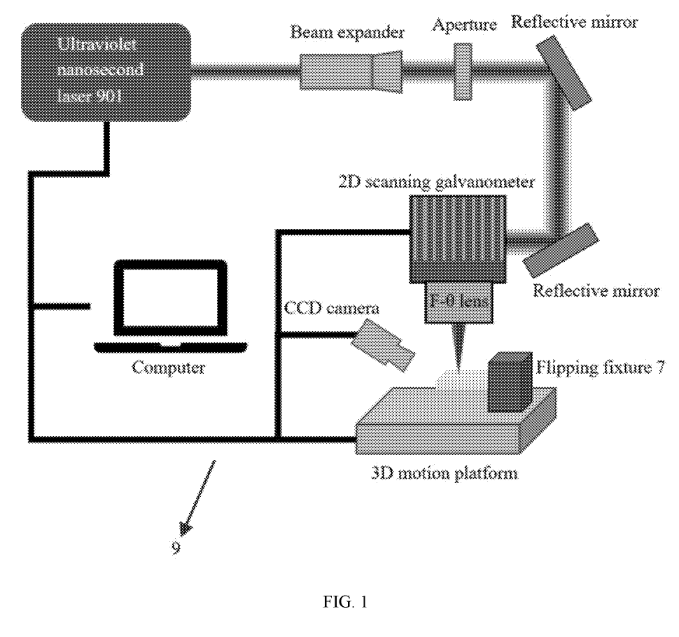

The disclosure provides the manufacturing method for the integrated diamond manifold microchannel heat sink structure, including the following steps.
1. The ultraviolet nanosecond laser processing system 9 with a central wavelength of 355 nm as shown in FIG. 1 is used. A laser repetition rate is set to 50 kHz, and a power factor is adjusted until a laser power of 10.5 W is measured with an ultraviolet laser energy meter.
2. A silicon wafer with a size of 10 mm × 10 mm × 0.6 mm is placed into the flipping fixture 7 shown in FIG. 2 and secured. A rotation angle of the stepper motor connected to the flipping fixture 7 is adjusted until the silicon wafer is horizontal. The 2D scanning galvanometer is used for scribing lines at different Z-axis heights, and the Z-axis height corresponding to the narrowest scribe mark is identified as a laser focal position. Then, a double-side-polished single-crystal diamond substrate 4 with a size of 10 mm × 10 mm × 0.6 mm is used for the next step of processing.
3. Furthermore, the ultraviolet nanosecond laser processing system 9 is used to fabricate the manifold structure 2 with a specific shape on the diamond substrate 4, as shown in an upper part of FIG. 4. This structure includes five inlet manifolds 12 and five outlet manifolds 13. Widths of the manifolds and fins range from 150 μm to 400 μm, and a depth of the manifolds ranges from 150 μm to 300 μm. A processing area of the manifold structure 2 is divided into a structural contour and an internal fill by using manifold processing parameters, with corresponding scanning paths designed. A scanning speed along the structural contour is 500 mm/s, with a number of scanning passes ranging from 100 to 350 in a clockwise direction and 100 to 350 in a counterclockwise direction. For the internal fill, a crisscross pattern with a 1 μm pitch is employed, with the scanning speed of 150 mm/s to 300 mm/s and a single pass.
4. Subsequently, the stepper motor is controlled to rotate the flipping fixture 7 by 180°, thereby positioning an unprocessed side of the diamond substrate 4 at the laser focal height. The ultraviolet nanosecond laser processing system 9 is then used to fabricate the microchannel structure 1 with a specific shape on this side, as shown in a lower part of FIG. 4. A width and pitch of the microchannels in the microchannel structure 1 range from 40 μm to 200 μm, a number of the microchannels ranges from 60 to 100, and a depth of the microchannels ranges from 300 μm to 450 μm. A processing area of the microchannel structure 1 is divided into a structural contour and an internal fill by using microchannel processing parameters, with corresponding scanning paths designed. The scanning speed along the structural contour is 500 mm/s, with a number of scanning passes ranging from 300 to 500 in the clockwise direction and 300 to 500 in the counterclockwise direction. For the internal fill, the crisscross pattern with a 1 μm pitch is employed, and the process is conducted in two stages to ensure the target depth is achieved and interconnectivity is realized. A stage is performed at the scanning speed of 250 mm/s to 350 mm/s, followed by another stage at the scanning speed of 400 mm/s to 480 mm/s.
5. After laser processing, the single-crystal diamond substrate 4 is removed and sequentially cleaned with acetone, anhydrous ethanol, and deionized water for 5 minutes each, followed by dried, and placed in a microwave plasma chemical vapor deposition system for the epitaxial lateral growth. The epitaxial lateral growth is terminated after reaching a thickness of approximately 200 μm, at which point a top of the microchannel structure 1 is sealed. Subsequently, the epitaxial lateral growth surface is ground and polished on a grinding and polishing machine, using diamond abrasive papers with grit numbers of 120, 600, 1200, and 3000 sequentially to achieve a surface roughness below 0.1 μm. The grinding and polishing machine rotates at a speed of 500 revolutions per minute (rpm), with continuous water irrigation applied during the process.
6. The ultraviolet nanosecond laser processing system 9 is used to fabricate two through-holes with diameters of 0.8 mm to 2 mm at predefined positions on the silicon wafer with a thickness of 0.2 mm. The through-holes serve as a water inlet hole 5 and a water outlet hole 6 (i.e., flow-guiding structures), respectively. The laser processing parameters employed are as follows. The scanning speed along a circular contour is 500 mm/s, with a number of scanning passes ranging from 150 to 400 in the clockwise direction and 150 to 400 in the counterclockwise direction. For internal fill, a crisscross pattern with a 1 μm pitch is employed, with the scanning speed of 150 mm/s to 250 mm/s and a single pass, thereby obtaining the manifold plate 3.
7. A high-vacuum sputtering coating system is used to deposit a Ti film with a thickness of approximately 20 nm on both a bottom surface of the manifold plate 3 and the upper surface of the manifold structure 2 to enhance wettability of the diamond. During Ti film deposition, a substrate temperature is maintained at 220° C, and a system vacuum degree is kept below 5×10⁻⁵ Pa. Finally, a vacuum brazing technology is employed to firmly bond the bottom surface of the manifold plate 3 to the upper surface of the manifold structure 2 with gold-tin (Au-Sn) solder, thereby forming the complete integrated diamond manifold microchannel heat sink. The vacuum brazing technology used here only requires bonding strength, with no specific thermal resistance requirement. This vacuum brazing technique is solely applied to connect the manifold plate 3 and the manifold structure 2, primary cooling capacity of the manifold microchannel heat sink relies on the microchannel structure 1 and the manifold structure 2. Consequently, even the use of a high thermal resistance bonding method will not compromise the designed cooling performance, thereby significantly reducing technical complexity of the bonding process.

### Embodiment 1

The disclosure provides a manufacturing method for the integrated diamond manifold microchannel heat sink structure, including the following steps.
1. The ultraviolet nanosecond laser processing system 9 with the central wavelength of 355 nm as shown in FIG. 1 is used. The laser repetition rate is set to 50 kHz, and the power factor is adjusted until the laser power of 10.5 W is measured with the ultraviolet laser energy meter.
2. The silicon wafer with the size of 10 mm × 10 mm × 0.6 mm is placed into the flipping fixture 7 shown in FIG. 2 and secured. The rotation angle of the stepper motor connected to the flipping fixture 7 is adjusted until the silicon wafer is horizontal. The 2D scanning galvanometer is used for scribing lines at different Z-axis heights, and the Z-axis height corresponding to the narrowest scribe mark is identified as the laser focal position. Then, the double-side-polished single-crystal diamond substrate 4 with the size of 10 mm × 10 mm × 0.6 mm is used for the next step of processing.
3. Furthermore, the ultraviolet nanosecond laser processing system 9 is used to fabricate the manifold structure 2 with the specific shape on the diamond substrate 4, as shown in the upper part of FIG. 4. This structure includes five inlet manifolds 12 and five outlet manifolds 13. The width of the manifolds and the fins is 400 μm, and the depth of the manifolds is 200 μm. The processing area of the manifold structure 2 is divided into the structural contour and the internal fill by using the manifold processing parameters, with the corresponding scanning paths designed. The scanning speed along the structural contour is 500 mm/s, with 175 scanning passes in the clockwise direction and 175 scanning passes in the counterclockwise direction. For the internal fill, the crisscross pattern with a 1 μm pitch is employed, with the scanning speed of 250 mm/s and a single pass.
4. Subsequently, the stepper motor is controlled to rotate the flipping fixture 7 by 180°, thereby positioning the unprocessed side of the diamond substrate 4 at the laser focal height. The ultraviolet nanosecond laser processing system 9 is then used to fabricate the microchannel structure 1 with the specific shape on this side, as shown in the lower part of FIG. 4. The width and pitch of the microchannels in the microchannel structure 1 is 200 μm, the number of the microchannels is 60, and the depth of the microchannels is 450 μm. The processing area of the microchannel structure 1 is divided into the structural contour and the internal fill by using the microchannel processing parameters, with the corresponding scanning paths designed. The scanning speed along the structural contour is 500 mm/s, with 500 scanning passes in the clockwise direction and 500 scanning passes in the counterclockwise direction. For the internal fill, the crisscross pattern with a 1 μm pitch is employed, and the process is conducted in two stages to ensure the target depth is achieved and interconnectivity is realized. A stage is performed at the scanning speed of 250 mm/s, followed by another stage at the scanning speed of 400 mm/s.
5. After laser processing, the single-crystal diamond substrate 4 is removed and sequentially cleaned with the acetone, the anhydrous ethanol, and the deionized water for 5 minutes each, followed by dried, and placed in the microwave plasma chemical vapor deposition system for the epitaxial lateral growth. The epitaxial lateral growth is terminated after reaching the thickness of approximately 200 μm, at which point the top of the microchannel structure 1 is sealed. Subsequently, the epitaxial lateral growth surface is ground and polished on the grinding and polishing machine, using the diamond abrasive papers with the grit numbers of 120, 600, 1200, and 3000 sequentially to achieve the surface roughness below 0.1 μm. The grinding and polishing machine rotates at the speed of 500 rpm, with the continuous water irrigation applied during the process.
6. The ultraviolet nanosecond laser processing system 9 is used to fabricate two through-holes with the diameter of 2 mm at the predefined positions on the silicon wafer with the thickness of 0.2 mm. The through-holes serve as the water inlet hole 5 and the water outlet hole 6, respectively. The laser processing parameters employed are as follows. The scanning speed along the circular contour is 500 mm/s, with 300 scanning passes in the clockwise direction and 300 scanning passes in the counterclockwise direction. For the internal fill, the crisscross pattern with a 1 μm pitch is employed, with the scanning speed of 200 mm/s and a single pass, thereby obtaining the manifold plate 3.
7. The high-vacuum sputtering coating system is used to deposit the Ti film with the thickness of approximately 20 nm on both the bottom surface of the manifold plate 3 and the upper surface of the manifold structure 2 to enhance the wettability of the diamond. During the Ti film deposition, the substrate temperature is maintained at 220° C, and the system vacuum degree is kept below 5×10⁻⁵ Pa. Finally, the vacuum brazing technology is employed to firmly bond the bottom surface of the manifold plate 3 to the upper surface of the manifold structure 2 with the Au-Sn solder, thereby forming the complete integrated diamond manifold microchannel heat sink. The vacuum brazing technology used here only requires the bonding strength, with no specific thermal resistance requirement. This vacuum brazing technique is solely applied to connect the manifold plate 3 and the manifold structure 2, the primary cooling capacity of the manifold microchannel heat sink relies on the microchannel structure 1 and the manifold structure 2. Consequently, even the use of the high thermal resistance bonding method will not compromise the designed cooling performance, thereby significantly reducing the technical complexity of the bonding process.

### Embodiment 2

The disclosure provides another manufacturing method for the integrated diamond manifold microchannel heat sink structure, including the following steps.
1. The ultraviolet nanosecond laser processing system 9 with the central wavelength of 355 nm as shown in FIG. 1 is used. The laser repetition rate is set to 50 kHz, and the power factor is adjusted until the laser power of 10.5 W is measured with the ultraviolet laser energy meter.
2. The silicon wafer with the size of 10 mm × 10 mm × 0.6 mm is placed into the flipping fixture 7 shown in FIG. 2 and secured. The rotation angle of the stepper motor connected to the flipping fixture 7 is adjusted until the silicon wafer is horizontal. The 2D scanning galvanometer is used for scribing lines at different Z-axis heights, and the Z-axis height corresponding to the narrowest scribe mark is identified as the laser focal position. Then, the double-side-polished single-crystal diamond substrate 4 with the size of 10 mm × 10 mm × 0.6 mm is used for the next step of the processing.
3. Furthermore, the ultraviolet nanosecond laser processing system 9 is used to fabricate the manifold structure 2 with the specific shape on the diamond substrate 4, as shown in the upper part of FIG. 4. This structure includes five inlet manifolds 12 and five outlet manifolds 13. The width of the manifolds and the fins is 300 μm, and the depth of the manifolds is 300 μm. The processing area of the manifold structure 2 is divided into the structural contour and the internal fill by using the manifold processing parameters, with the corresponding scanning paths designed. The scanning speed along the structural contour is 500 mm/s, with 350 scanning passes in the clockwise direction and 350 scanning passes in the counterclockwise direction. For the internal fill, the crisscross pattern with a 1 μm pitch is employed, with the scanning speed of 150 mm/s and a single pass.
4. Subsequently, the stepper motor is controlled to rotate the flipping fixture 7 by 180°, thereby positioning the unprocessed side of the diamond substrate 4 at the laser focal height. The ultraviolet nanosecond laser processing system 9 is then used to fabricate the microchannel structure 1 with the specific shape on this side, as shown in the lower part of FIG. 4. The width and pitch of the microchannels in the microchannel structure 1 is 150 μm, the number of the microchannels is 80, and the depth of the microchannels is 400 μm. The processing area of the microchannel structure 1 is divided into the structural contour and the internal fill by using the microchannel processing parameters, with the corresponding scanning paths designed. The scanning speed along the structural contour is 500 mm/s, with 450 scanning passes in the clockwise direction and 450 scanning passes in the counterclockwise direction. For the internal fill, the crisscross pattern with a 1 μm pitch is employed, and the process is conducted in two stages to ensure the target depth is achieved and the interconnectivity is realized. A stage is performed at the scanning speed of 280 mm/s, followed by another stage at the scanning speed of 480 mm/s.
5. After laser processing, the single-crystal diamond substrate 4 is removed and sequentially cleaned with the acetone, the anhydrous ethanol, and the deionized water for 5 minutes each, followed by dried, and placed in the microwave plasma chemical vapor deposition system for the epitaxial lateral growth. The epitaxial lateral growth is terminated after reaching the thickness of approximately 200 μm, at which point the top of the microchannel structure 1 is sealed. Subsequently, the epitaxial lateral growth surface is ground and polished on the grinding and polishing machine, using the diamond abrasive papers with the grit numbers of 120, 600, 1200, and 3000 sequentially to achieve the surface roughness below 0.1 μm. The grinding and polishing machine rotates at the speed of 500 rpm, with the continuous water irrigation applied during the process.
6. The ultraviolet nanosecond laser processing system 9 is used to fabricate two through-holes with the diameter of 1.2 mm at the predefined positions on the silicon wafer with the thickness of 0.2 mm. The through-holes serve as the water inlet hole 5 and the water outlet hole 6, respectively. The laser processing parameters employed are as follows. The scanning speed along the circular contour is 500 mm/s, with 400 scanning passes in the clockwise direction and 400 scanning passes in the counterclockwise direction. For the internal fill, the crisscross pattern with a 1 μm pitch is employed, with the scanning speed of 250 mm/s and a single pass, thereby obtaining the manifold plate 3.
7. The high-vacuum sputtering coating system is used to deposit the Ti film with the thickness of approximately 20 nm on both the bottom surface of the manifold plate 3 and the upper surface of the manifold structure 2 to enhance the wettability of the diamond. During the Ti film deposition, the substrate temperature is maintained at 220°, and the system vacuum degree is kept below 5×10⁻⁵ Pa. Finally, the vacuum brazing technology is employed to firmly bond the bottom surface of the manifold plate 3 to the upper surface of the manifold structure 2 with the Au-Sn solder, thereby forming the complete integrated diamond manifold microchannel heat sink. The vacuum brazing technology used here only requires the bonding strength, with no specific thermal resistance requirement. This vacuum brazing technique is solely applied to connect the manifold plate 3 and the manifold structure 2, the primary cooling capacity of the manifold microchannel heat sink relies on the microchannel structure 1 and the manifold structure 2. Consequently, even the use of the high thermal resistance bonding method will not compromise the designed cooling performance, thereby significantly reducing the technical complexity of the bonding process.

### Embodiment 3

The disclosure provides still another manufacturing method for the integrated diamond manifold microchannel heat sink structure, including the following steps.
1. The ultraviolet nanosecond laser processing system 9 with the central wavelength of 355 nm as shown in FIG. 1 is used. The laser repetition rate is set to 50 kHz, and the power factor is adjusted until the laser power of 10.5 W is measured with the ultraviolet laser energy meter.
2. The silicon wafer with the size of 10 mm × 10 mm × 0.6 mm is placed into the flipping fixture 7 shown in FIG. 2 and secured. The rotation angle of the stepper motor connected to the flipping fixture 7 is adjusted until the silicon wafer is horizontal. The 2D scanning galvanometer is used for scribing lines at different Z-axis heights, and the Z-axis height corresponding to the narrowest scribe mark is identified as the laser focal position. Then, the double-side-polished single-crystal diamond substrate 4 with the size of 10 mm × 10 mm × 0.6 mm is used for the next step of the processing.
3. Furthermore, the ultraviolet nanosecond laser processing system 9 is used to fabricate the manifold structure 2 with the specific shape on the diamond substrate 4, as shown in the upper part of FIG. 4. This structure includes five inlet manifolds 12 and five outlet manifolds 13. The width of the manifolds and the fins is 150 μm, and the depth of the manifolds is 150 μm. The processing area of the manifold structure 2 is divided into the structural contour and the internal fill by using the manifold processing parameters, with the corresponding scanning paths designed. The scanning speed along the structural contour is 500 mm/s, with 100 scanning passes in the clockwise direction and 100 scanning passes in the counterclockwise direction. For the internal fill, the crisscross pattern with a 1 μm pitch is employed, with the scanning speed of 300 mm/s and a single pass.
4. Subsequently, the stepper motor is controlled to rotate the flipping fixture 7 by 180°, thereby positioning the unprocessed side of the diamond substrate 4 at the laser focal height. The ultraviolet nanosecond laser processing system 9 is then used to fabricate the microchannel structure 1 with the specific shape on this side, as shown in the lower part of FIG. 4. The width and pitch of the microchannels in the microchannel structure 1 is 40 μm, the number of the microchannels is 100, and the depth of the microchannels is 300 μm. The processing area of the microchannel structure 1 is divided into the structural contour and the internal fill by using the microchannel processing parameters, with the corresponding scanning paths designed. The scanning speed along the structural contour is 500 mm/s, with 300 scanning passes in the clockwise direction and 300 scanning passes in the counterclockwise direction. For the internal fill, the crisscross pattern with a 1 μm pitch is employed, and the process is conducted in two stages to ensure the target depth is achieved and the interconnectivity is realized. A stage is performed at the scanning speed of 350 mm/s, followed by another stage at the scanning speed of 450 mm/s.
5. After laser processing, the single-crystal diamond substrate 4 is removed and sequentially cleaned with the acetone, the anhydrous ethanol, and the deionized water for 5 minutes each, followed by dried, and placed in the microwave plasma chemical vapor deposition system for the epitaxial lateral growth. The epitaxial lateral growth is terminated after reaching the thickness of approximately 200 μm, at which point the top of the microchannel structure 1 is sealed. Subsequently, the epitaxial lateral growth surface is ground and polished on the grinding and polishing machine, using the diamond abrasive papers with the grit numbers of 120, 600, 1200, and 3000 sequentially to achieve the surface roughness below 0.1 μm. The grinding and polishing machine rotates at the speed of 500 rpm, with the continuous water irrigation applied during the process.
6. The ultraviolet nanosecond laser processing system 9 is used to fabricate two through-holes with the diameter of 0.8 mm at the predefined positions on the silicon wafer with the thickness of 0.2 mm. The through-holes serve as the water inlet hole 5 and the water outlet hole 6, respectively. The laser processing parameters employed are as follows. The scanning speed along the circular contour is 500 mm/s, with 150 scanning passes in the clockwise direction and 150 scanning passes in the counterclockwise direction. For the internal fill, the crisscross pattern with a 1 μm pitch is employed, with the scanning speed of 150 mm/s and a single pass, thereby obtaining the manifold plate 3.
7. The high-vacuum sputtering coating system is used to deposit the Ti film with the thickness of approximately 20 nm on both the bottom surface of the manifold plate 3 and the upper surface of the manifold structure 2 to enhance the wettability of the diamond. During the Ti film deposition, the substrate temperature is maintained at 220℃, and the system vacuum degree is kept below 5×10⁻⁵ Pa. Finally, the vacuum brazing technology is employed to firmly bond the bottom surface of the manifold plate 3 to the upper surface of the manifold structure 2 with the Au-Sn solder, thereby forming the complete integrated diamond manifold microchannel heat sink. The vacuum brazing technology used here only requires the bonding strength, with no specific thermal resistance requirement. This vacuum brazing technique is solely applied to connect the manifold plate 3 and the manifold structure 2, the primary cooling capacity of the manifold microchannel heat sink relies on the microchannel structure 1 and the manifold structure 2. Consequently, even the use of the high thermal resistance bonding method will not compromise the designed cooling performance, thereby significantly reducing the technical complexity of the bonding process.

What is claimed is:

1. An integrated diamond manifold microchannel heat sink structure, comprising: a microchannel structure (1), a manifold structure (2), and a manifold plate (3); wherein the manifold structure (2) and the microchannel structure (1) are both integrated on a diamond substrate (4); the microchannel structure (1) is connected to the manifold structure (2), and a surface where the microchannel structure (1) is located is sealed; the manifold structure (2) is connected to the manifold plate (3); and the manifold plate (3) is defined with flow-guiding structures penetrating therethrough.

2. The integrated diamond manifold microchannel heat sink structure as claimed in claim 1, wherein the diamond substrate (4) has a thickness of 0.6 millimeters (mm); the manifold structure (2) is machined to a depth of 0.25 mm; and the microchannel structure (1) has a depth of 0.35 mm.

3. A manufacturing method for the integrated diamond manifold microchannel heat sink structure as claimed in claim 1, comprising the following steps:
based on an ultraviolet nanosecond laser processing system (9), removing materials from one side of a double-side polished diamond substrate (4) by using manifold processing parameters according to a designed shape of the manifold structure (2) to obtain a diamond substrate (4) with a machined manifold structure (2);
based on the ultraviolet nanosecond laser processing system (9), flipping the diamond substrate (4) with the machined manifold structure (2) by 180°, and removing materials from the other side of the diamond substrate (4) with the machined manifold structure (2) by using microchannel processing parameters according to a designed shape of the microchannel structure (1) to form the microchannel structure (1), wherein the microchannel structure (1) is connected to the manifold structure (2);
performing epitaxial lateral growth on a microchannel side of the diamond substrate (4) with the manifold structure (2) and the microchannel structure (1) until a top of the microchannel structure (1) is sealed;
based on the ultraviolet nanosecond laser processing system (9), processing the flow-guiding structures on a double-side polished silicon wafer by using the manifold processing parameters according to a designed shape of the flow-guiding structures, wherein the flow-guiding structures penetrate through upper and lower surfaces of the double-side polished silicon wafer, thereby obtaining the manifold plate (3);
metallizing a side of the manifold plate (3) and a surface of the manifold structure (2) to obtain a metallized manifold plate (3) and a metallized manifold structure (2);
bonding the metallized manifold plate (3) and the metallized manifold structure (2).

4. The manufacturing method as claimed in claim 3, wherein in the ultraviolet nanosecond laser processing system (9), a laser (901) has a central wavelength of 355 nanometers (nm) and a pulse width of 15 nanoseconds (ns).

5. The manufacturing method as claimed in claim 3, wherein for all laser processing steps, laser parameters are used as follows: a power of 10.5 watts (W), and a repetition rate of 50 kilohertz (kHz).

6. The manufacturing method as claimed in claim 3, wherein after the top of the microchannel structure (1) is sealed, the diamond substrate (4) with the epitaxial lateral growth is polished to achieve a surface roughness below 0.1 micrometers (μm).

7. The manufacturing method as claimed in claim 4, wherein a processing area of the manifold structure (2) is divided into a structural contour and an internal fill; a scanning speed along the structural contour is 500 millimeters per second (mm/s), with 200 clockwise passes and 200 counterclockwise passes; for the internal fill, a crisscross pattern with a 1 μm pitch is employed, with a scanning speed of 240 mm/s and a single pass.

8. The manufacturing method as claimed in claim 4, wherein a processing area of the microchannel structure (1) is divided into a structural contour and an internal fill; a scanning speed along the structural contour is 500 mm/s, with 400 clockwise passes and 400 counterclockwise passes; for the internal fill, a crisscross pattern with a 1 μm pitch is used, processed in two stages to achieve a depth of 350 μm with one of the two stages at a scanning speed of 340 mm/s and the other of the two stages at a scanning speed of 430 mm/s.

9. The manufacturing method as claimed in claim 3, wherein when metallizing the side of the manifold plate (3) and the surface of the manifold structure (2), a magnetron sputtering process is employed to deposit a titanium (Ti) film onto the side of the manifold plate (3) and the surface of the manifold structure (2); during deposition, a substrate temperature is maintained at 220 Celsius degrees (℃), with a vacuum degree below 5×10⁻⁵ pascals (Pa).

10. The manufacturing method as claimed in claim 3, wherein when bonding the metallized manifold plate (3) and the metallized manifold structure (2), a vacuum brazing process is employed.
